(19) United States
(12) Patent Application Publication
(10) Pub. No.: US 2016/0204266 A1
(43) Pub. Date: Jul. 14, 2016

(54) THIN FILM TRANSISTOR ARRAY PANEL AND MANUFACTURING METHOD THEREOF

(71) Applicant: Samsung Display CO., Ltd., Yongin-Si (KR)

(72) Inventors: Ki Seong SEO, Seoul (KR); Jung Yun JO, Namyangju-si (KR)

(21) Appl. No.: 14/879,283

(22) Filed: Oct. 9, 2015

(30) Foreign Application Priority Data
Jan. 8, 2015 (KR) 10-2015-0002974

(51) Int. Cl. H01L 29/786; H01L 23/31; H01L 21/425; H01L 29/66; H01L 29/423; H01L 29/24; H01L 23/29

(52) U.S. Cl. CPC H01L 29/7869; H01L 29/24; H01L 29/78696; H01L 23/3171; H01L 23/291; H01L 29/66969; H01L 29/42384; H01L 21/425

(57) ABSTRACT

A thin film transistor array panel and method of manufacturing. The thin film transistor array panel includes a substrate, a first gate electrode positioned on the substrate, a gate insulating layer positioned on the first gate, an oxide semiconductor positioned on the gate insulating layer and including a channel region, at least one etch stopper positioned on the oxide semiconductor, a second gate electrode, a source electrode and a drain electrode positioned on the at least one etch stopper, a passivation layer formed on the second gate electrode, the source electrode and the drain electrode; and a pixel electrode positioned on the passivation layer and connected to the drain electrode, in which the oxide semiconductor includes an N+ region formed in a portion exposed through the at least one etch stopper.

### CLAIM OF PRIORITY

This application claims priority to and the benefit of Korean Patent Application No. 10-2015-0002974 filed in the Korean Intellectual Property Office on Jan. 8, 2015, the entire contents of which are incorporated herein by reference.

### BACKGROUND OF THE INVENTION

1. Field of the Invention

The present invention generally relates to a thin film transistor array panel and a manufacturing method thereof.

2. Description of the Related Art

Flat panel displays may be used as display devices and include various devices such as liquid crystal displays, organic light emitting display devices, plasma display devices, electrophoretic displays, electrowetting display devices, etc.

The Description of the Related Art is made to help understanding the background of the present invention and may include matters out of the related art known to those skilled in the art.

The above information disclosed in this section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a thin film transistor array panel and a manufacturing method thereof having advantages of having excellent performance by forming an N+ region in an entire region of an oxide semiconductor exposed through an etch stopper to reduce resistance of an oxide semiconductor channel. An exemplary embodiment of the present invention provides a thin film transistor array panel and a manufacturing method thereof. Another embodiment of the present invention provides,

Yet another embodiment of the present invention provides

According to an embodiment of the present invention,

The present invention has been made in an effort to provide a thin film transistor array panel and a manufacturing method thereof having advantages of having excellent performance by forming an N+ region in an entire region of an oxide semiconductor exposed through an etch stopper to reduce resistance of an oxide semiconductor channel.

An exemplary embodiment of the present invention provides a thin film transistor array panel including a substrate, a first gate electrode positioned on the substrate, a gate insulating layer positioned on the first gate, an oxide semiconductor positioned on the gate insulating layer and including a channel region, one or more etch stoppers positioned on the oxide semiconductor, a second gate electrode, a source electrode, and a drain electrode positioned on each of the etch stoppers, a passivation layer formed on the second gate electrode, the source electrode and the drain electrode; and a pixel electrode positioned on the passivation layer and connected to the drain electrode, wherein the oxide semiconductor includes an N+ region formed in a portion exposed through the at least one etch stopper.

The N+ region may have one side that is in contact with the gate insulating layer, and the N+ region may have the other side that is in contact with the source electrode or the drain electrode.

The N+ region may be positioned between the etch stoppers and includes first and second N+ regions positioned at both sides of the first gate electrode.

At least one of the etch stoppers may include first to third etch stoppers.

The first etch stopper may be formed on the first gate electrode, and the second and third etch stoppers may be formed at both sides of the first etch stopper and be partially in contact with the oxide semiconductor.

The second and third etch stoppers may be in contact with both ends of the oxide semiconductor and the gate insulating layer.

The source electrode and the drain electrode may cover the second etch stopper and the third etch stopper, respectively.

The second gate electrode may have a narrower width than the first gate electrode.

The oxide semiconductor may include a titanium-indium-zinc oxide (TIZO) containing a combination of titanium (Ti), indium (In) and zinc (Zn).

At least one channel region of the oxide semiconductor may include a first channel region and a second channel region, and the first channel region is positioned above the gate insulating layer, and the second channel region is positioned under the first etch stopper.

The passivation layer may include fluorine-containing silicon oxide (SiOF).

Another embodiment of the present invention provides a manufacturing method of a thin film transistor array panel including forming a first gate electrode on a substrate, forming a gate insulating layer on the first gate electrode, forming an oxide semiconductor including a channel region on the gate insulating layer, forming one or more etch stoppers on the oxide semiconductor, forming an N+ region in an exposed portion of the oxide semiconductor, forming a second gate electrode, a source electrode and a drain electrode on the at least one etch stopper, and forming a passivation layer on the second gate electrode, the source electrode and the drain electrode.

The forming of the N+ region may include forming a photo resist (PR) on each of the etch stoppers and forming an N+ region using the PR as a mask, wherein the N+ region is formed in a portion exposed through the at least one of the etch stoppers in the oxide semiconductor.

The forming of the N+ region may be performed by one of an ion implantation method and an inductively coupled plasma (ICP) method.

The inductively coupled plasma method may include injecting fluorine to form the N+ region.

The N+ region may have one side that is in contact with the gate insulating layer, and the N+ region may have the other side that is in contact with the source electrode or the drain electrode.

The N+ region may be positioned between the etch stoppers and include first and second N+ regions positioned at both sides of the first gate electrode.

The forming of the source electrode and the drain electrode may include the source electrode and the drain electrode to be partially in contact with the oxide semiconductor.

The forming of the etch stoppers may further include forming a first etch stopper on the oxide semiconductor, and forming second and third etch stoppers at both sides of the first etch stopper.

The forming of the second and third etch stoppers may include the second and third etch stoppers to be in contact with both ends of the oxide semiconductor and the gate insulating layer.

According to an embodiment of the present invention, the thin film transistor array panel can provide a thin film transistor array panel having excellent performance by forming an N+ region in an entire region of an oxide semiconductor exposed through an etch stopper to reduce resistance of an oxide semiconductor channel, and a manufacturing method thereof.

In addition, effects obtained or predicted by the exemplary embodiment of the present invention will be directly or implicitly disclosed in detailed description of the exemplary embodiment of the present invention. In other words, various effects predicted according to the exemplary embodiment of the present invention will be disclosed in detailed description to be described below.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a cross-sectional view illustrating a structure of a thin film transistor array panel according to an exemplary embodiment of the present invention.

FIG. 2 to FIG. 4 are drawings illustrating a manufacturing process of a thin film transistor array panel according to an exemplary embodiment of the present invention.

FIG. 5 is a top plan view schematically illustrating a structure of a display device according to an exemplary embodiment including the thin film transistor array panel of FIG. 1.

FIG. 6 is a circuit diagram illustrating a pixel circuit included in the display device of FIG. 5.

FIG. 7 is a layout view illustrating one pixel included in the display device of FIG. 5.

FIG. 8 is a cross-sectional view taken along line IV-IV of FIG. 7.

FIG. 9 is a cross-sectional view taken along line V-V of FIG. 7.

FIG. 10 is a top plan view schematically illustrating a structure of a display device according to another exemplary embodiment including the thin film transistor array panel of FIG. 1.

FIG. 11 is a cross-sectional view taken along line VI-VI of FIG. 10.

### DETAILED DESCRIPTION OF THE INVENTION

Hereinafter, exemplary embodiments of the present invention will be described in detail with reference to the accompanying drawings. This invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the thicknesses of layers and regions are exaggerated for clarity. Also, when it is mentioned that a layer is on another layer or on a substrate, it can be directly formed on the other layer or on the substrate, or the third layer can be interposed therebetween. Like reference numerals refer to like elements throughout.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like or similar reference numerals refer to like or similar elements throughout. As used herein, the term “and/or” includes any and all combinations of one or more of the associated listed items.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross sectional illustrations that are schematic illustrations of illustratively idealized example embodiments (and intermediate structures) of the inventive concept. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of the inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

A liquid crystal display, which is currently one of the most widely used flat panel displays and includes two display panels having electric field generating electrodes such as a pixel electrode and a common electrode formed therein, a liquid crystal layer disposed between the two display panels, and a backlight unit configured to provide light to the display panels having the liquid crystal layer disposed therebetween.

A liquid crystal display applies a voltage to an electric field generating electrode to generate an electric field in a liquid crystal layer, determines directions of liquid crystal molecules of the liquid crystal layer through the generated electric field, and controls an output amount of light provided by a backlight unit, thereby displaying an image.

In general, a display device having a liquid crystal display includes a thin film transistor array panel.

A thin film transistor array panel includes a gate electrode that is a part of a gate wire, a semiconductor layer that forms a channel, and a source electrode and a drain electrode that are a part of a data wire.

Such a thin film transistor is a switching element that transfers an image signal transferred to a pixel electrode through a data wire or interrupts the image signal according to a scanning signal transferred through a gate wire.

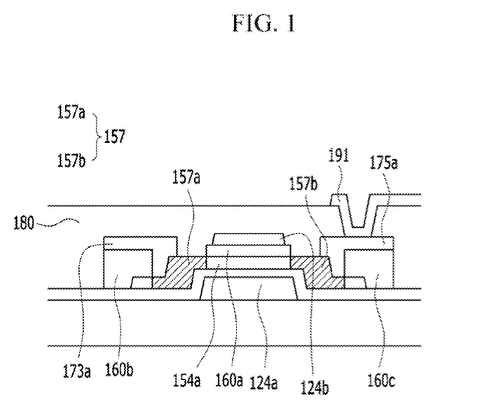

Hereinafter, referring to FIG. 1, a thin film transistor array panel according to an exemplary embodiment of the present invention will be described.

FIG. 1 is a cross-sectional view illustrating a structure of a thin film transistor array panel according to an exemplary embodiment of the present invention.

As shown in FIG. 1, in a thin film transistor array panel 100, a first gate electrode 124a is formed on an insulation substrate 110 made of transparent glass or plastic.

A gate insulating layer 140 made of an insulating material such as a silicon oxide (SiOx), a silicon nitride (SiNx), or silicon monooxide (SiO) may be formed on the first gate electrode 124a. The gate insulating layer 140 may be formed using a sputtering method and have a dual-layer structure.

A first oxide semiconductor 154a including a channel region may be formed on the gate insulating layer 140. The first oxide semiconductor 154a is a metal oxide semiconductor, and may be made of an oxide of a metal such as zinc (Zn), indium (In), gallium (Ga), tin (Sn) and titanium (Ti) or a combination of a metal such as zinc (Zn), indium (In), gallium (Ga), tin (Sn) and titanium (Ti) with an oxide thereof.

For example, the first oxide semiconductor 154a may include at least one of zinc oxide (ZnO), indium oxide (InO), zinc-tin oxide (ZTO), zinc-indium oxide (IGZO), titanium oxide (TiO), indium-gallium-zinc oxide (IGZO), titanium-indium-zinc oxide (TIZO).

The first oxide semiconductor 154a includes a channel region. The channel region includes a first channel region and a second channel region. The first channel region may be positioned above the gate insulating layer 140, and the second channel region may be positioned under a first etch stopper 160a.

In the first oxide semiconductor 154a, a portion excluding a region protected by an etch stopper 160 to be described is N+ doped and thus an N+ region 157 may be formed in the portion. The N+ region 157 will be described below in greater detail.

The at least one etch stopper 160 may be formed on the first oxide semiconductor 154a. The etch stopper 160 includes first to third etch stoppers 160a, 160b and 160c, and the first etch stopper 160a may be formed on the first gate electrode 124a. In other words, the first etch stopper 160a may be formed on the channel region of the first oxide semiconductor 154a and may prevent the channel region that is a channel of the thin film transistor from being damaged by an etchant in a subsequent process.

In addition, the first etch stopper 160a may block diffusion of impurities such as hydrogen into the channel region from an insulating layer such as a passivation layer 180 to be described or the outside to prevent properties of the channel region from being changed.

Also the second and third etch stoppers 160b and 160c are formed at both sides of the first etch stopper 160a. The second and third etch stoppers 160b and 160c come into contact with a part of both ends of the first oxide semiconductor 154a and a part of the gate insulating layer 140.

The at least one etch stopper 160 may be made of an inorganic film including at least one material of SiOx, SiNx, SiOCx or SiONx, or an organic film including an organic material or a polymer organic material.

The at least one etch stopper 160 serves to protect the first oxide semiconductor 154a when the N+ region 157 may be formed in the first oxide semiconductor 154a, and the N+ region 157 may be formed in the region of the first oxide semiconductor 154a exposed through the at least one etch stopper 160.

In other words, to describe the N+ region 157 of the first oxide semiconductor 154a in greater detail, one side of the N+ region 157 comes into contact with the gate insulating layer 140, and the other side of the N+ region 157 comes into contact with a first source electrode 173a or a first drain electrode 175a which will be described below. The N+ region 157 includes the first and second N+ regions 157a and 157b. In addition, the first N+ region 157a may be formed between the first etch stopper 160a and the second etch stopper 160b, and the second N+ region 157b may be formed between the first etch stopper 160a and the third etch stopper 160c. In this case, positions of the first to third etch stoppers 160 and the first and second N+ regions 157 may be changed.

A second gate electrode 124b, the first source electrode 173a and the first drain electrode 175a are formed above the at least one etch stopper 160, respectively.

The second gate electrode 124b, the first source electrode 173a and the first drain electrode 175a are formed on the first etch stopper 160a, the second etch stopper 160b and the third etch stopper 160c, respectively.

Also the first source electrode 173a and the first drain electrode 175a cover the second etch stopper 160b and the third etch stopper 160c, respectively. In this case, the second gate electrode 124b may have a narrower width than the first gate electrode 124a. That is, the first source electrode 173a and the first drain electrode 175a are positioned at both sides of a channel region centered therebetween, and separated from each other. The first source electrode 173a and the first drain electrode 175a may or may not substantially overlap the second gate electrode 124b. The first source electrode 173a and the first drain electrode 175a are physically and electrically connected to the channel region and may have conductivity. Specifically, the first source electrode 173a and the first drain electrode 175a overlap the first oxide semiconductor 154a serving as a channel region, but carrier concentration of the first source electrode 173a and the first drain electrode 175a is different from carrier concentration of the channel region.

The passivation layer 180 is formed on the second gate electrode 124b, the first source electrode 173a and the first drain electrode 175a. The passivation layer 180 is made of an inorganic insulator such as silicon nitride or silicon oxide, an organic insulator and a low dielectric constant insulator. Dielectric constants of the organic insulator and the low dielectric constant insulator may be 4.0 or less and examples of the low dielectric constant insulator may include a fluorine-containing oxide (a-SiOF) formed by plasma chemical vapor deposition (PECVD). Thus, the passivation layer 180 may be made of, for example, an insulating material such as a silicon oxide (SiOx), a silicon nitride (SiNx), silicon oxynitride (SiON) and silicon oxyfluoride (SiOF).

Also a pixel electrode 191 may be positioned on the passivation layer 180 and connected to the first drain electrode 175a.

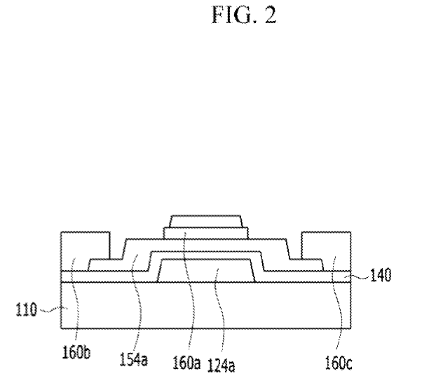

Hereinafter, a process of manufacturing the thin film transistor array panel 100 having the structure described above will be described with reference to FIG. 2 to FIG. 4.

FIG. 2 to FIG. 4 are drawings illustrating a manufacturing process of the thin film transistor array panel 100 according to an exemplary embodiment of the present invention, and detailed description of a typical manufacturing process will be omitted.

Referring to FIG. 2, first, the first gate electrode 124a may be formed on the insulation substrate 110 made of transparent glass or plastic.

Next, the gate insulating layer 140 made of a silicon nitride (SiNx), a silicon oxide (SiOx) or silicon monooxide (SiO) may be formed on the first gate electrode 124a.

Next, the first oxide semiconductor 154a made of an oxide of a metal such as zinc (Zn), indium (In), gallium (Ga), tin (Sn) and titanium (Ti) or a combination of a metal such as zinc (Zn), indium (In), gallium (Ga), tin (Sn) and titanium (Ti) with an oxide thereof may be formed above the gate insulating layer 140. In this case, the first etch stopper 160a may be formed on a protruding upper portion of the first oxide semiconductor 154a, and the second and third etch stoppers 160b and 160c are formed at both sides of the first oxide semiconductor 154a. The second and third etch stoppers 160b and 160c come into contact with a part of the both sides of the first oxide semiconductor 154a and a part of the gate insulating layer 140.

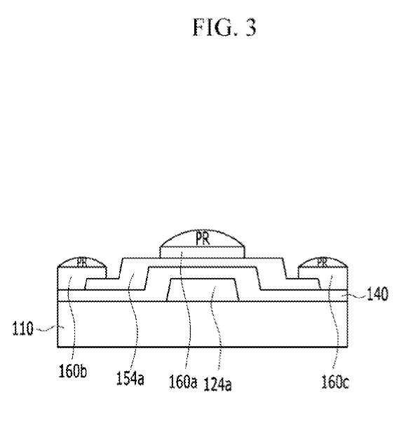

Referring to FIG. 3, next, a photoresist (PR) may be formed on the first to third etch stoppers 160. Here, the photoresist is made of a polymer compound having photosensitivity, an adhesive property and corrosion resistance.

In an exemplary embodiment of the present invention, a negative resist will be described by way of example. Such a negative resist is a kind of photoresist and is a resist that becomes insoluble in a developer when exposed to light.

After a photoresist film may be formed on the first oxide semiconductor 154a and the first to third etch stoppers 160, a photo process may be performed using a mask disposed on the photoresist film. After such a photo process, the photoresist present on the first oxide semiconductor 154a is etched, but the photoresist present on the first to third etch stoppers 160 is not etched. Thus, the photoresist present on the first to third etch stoppers 160 remains.

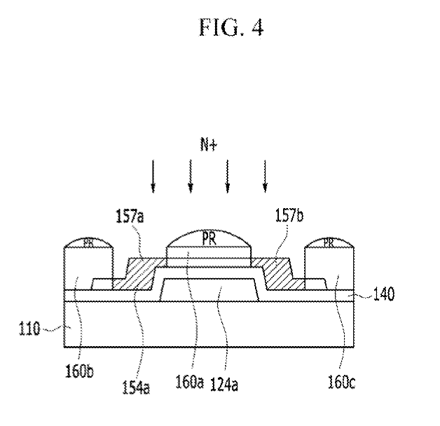

Referring to FIG. 4, the first oxide semiconductor 154a is N+ doped using the remaining photoresist on the first to third etch stoppers 160 as a mask and thus the N+ region 157 is formed in the first oxide semiconductor 154a. In this case, a method of forming the N+ region 157 may be performed using an ion implantation method or an inductively coupled plasma (ICP) method.

The ion implantation method may be performed in a vacuum and/or at room temperature, in which N+ ions are accelerated to dozens to hundreds of keV to generate an ion beam and then injected into the first oxide semiconductor 154a to form the N+ region 157 in the first oxide semiconductor 154a.

The method of forming the N+ region 157 using the inductively coupled plasma method causes an electrical plasma state by flowing a mixture of an inert gas such as argon and a spray sample along an axis of a high frequency coil. Also, light emission caused by this is used as a light source. The first oxide semiconductor 154a is N+ doped using such a light source to form the N+ region 157.

In this case, in the inductively coupled plasma method, fluorine is injected into the first oxide semiconductor 154a to form the N+ region 157.

When the N+ region 157 may be formed in the first oxide semiconductor 154a as described above, an entire region of the first oxide semiconductor 154a excluding the region in which the first to third etch stoppers 160 are positioned is N+ doped. The first oxide semiconductor 154a including the N+ region 157 has excellent conductivity like a conductor.

Next, the photoresist is removed, and the second gate electrode 124b, the first source electrode 173a and the first drain electrode 175a are formed on the first to third etch stoppers 160, respectively. The second gate electrode 124b may be formed on the first etch stopper 160a, and may have a narrower width than the first gate electrode 124a.

Also the first source electrode 173a and the first drain electrode 175a are formed on the second and third etch stoppers 160b and 160c and cover the second and third etch stoppers 160b and 160c.

Finally, the passivation layer 180 may be formed on the uppermost portion of the thin film transistor array panel 100. The passivation layer 180 may be made of an insulating material such as a silicon oxide (SiOx), a silicon nitride (SiNx), silicon oxynitride (SiON) and silicon oxyfluoride (SiOF). Next, the pixel electrode 191 connected to the first drain electrode 175a may be formed.

Hereinafter, a display device that may be formed using the thin film transistor array panel 100 manufactured as described above as a switching transistor will be described.

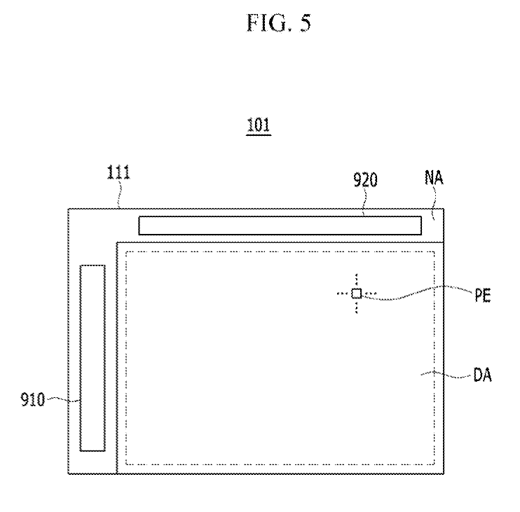

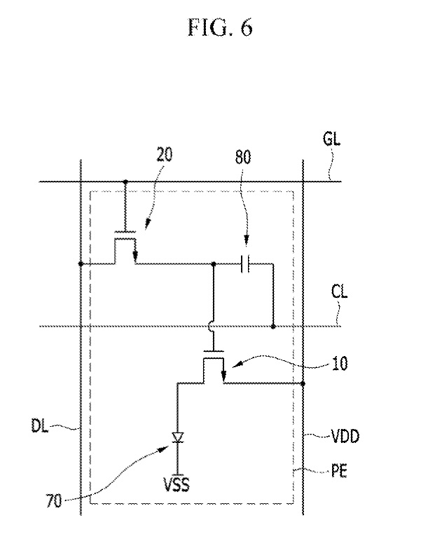

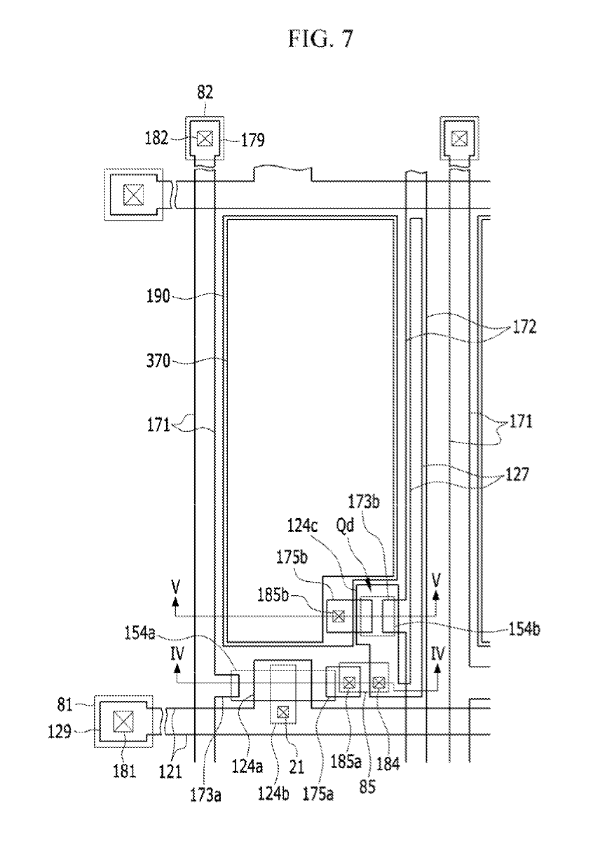

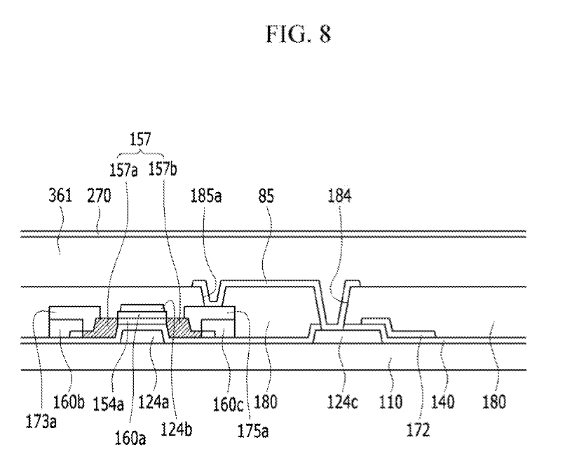

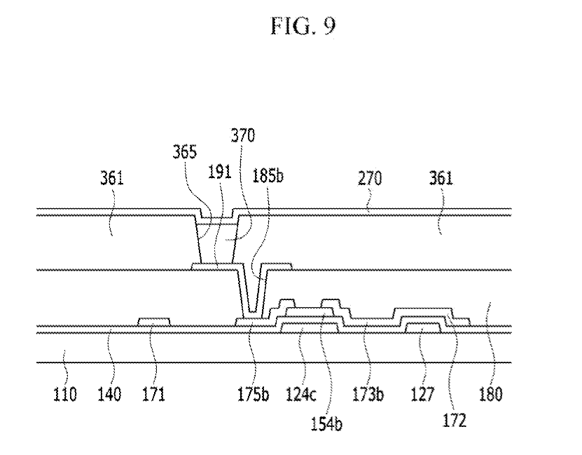

FIG. 5 is a top plan view schematically illustrating a structure of a display device according to an exemplary embodiment including the thin film transistor array panel of FIG. 1. FIG. 6 is a circuit diagram illustrating a pixel circuit included in the display device of FIG. 5. FIG. 7 is a layout view illustrating one pixel included in the display device of FIG. 5. FIG. 8 is a cross-sectional view taken along line IV-IV of FIG. 7. FIG. 9 is a cross-sectional view taken along line V-V of FIG. 7.

As shown in FIG. 5, the display device includes a substrate main body III which is divided into a display area DA and a non-display area NA. A plurality of pixel areas PE are formed in the display area DA of the substrate main body 111, images are displayed in the pixel areas, and at least one driving circuit 910 or 920 may be formed in the non-display area NA. Here, the pixel area (PE) is a region in which a pixel that is a minimum unit displaying an image is formed. However, in the exemplary embodiment of the present invention, both of the driving circuits 910 and 920 need not necessarily be formed in the non-display area (NA), and one or both of the driving circuits 910 and 920 may be omitted.

As shown in FIG. 6, the display device according to the exemplary embodiment of the present invention is an organic light emitting display device having a 2Tr-1Cap structure in which an organic light emitting diode (OLED) 70, two thin film transistors 10 and 20 and one capacitor 80 are disposed for one pixel area PE. However, the exemplary embodiment of the present invention is not limited thereto. Thus, the display device may be an organic light emitting display device having a structure in which at least three thin film transistors and at least two capacitors are disposed for one pixel area PE. In addition, the display device that is formed using the thin film transistor array panel 100 according to the exemplary embodiment of the present invention as a switching transistor may also be applied to a light-emitting device (LED) as well as an organic light emitting display device.

Further, the display device may be formed to have various structures in which a separate wiring is further formed. As described above, the thin film transistor array panel 100 may be configured as a component of at least one compensation circuit of an additionally formed thin film transistor and capacitor.

The compensation circuit improves uniformity of the organic light emitting element 70 formed for each pixel area (PE) and suppresses deviation in image quality. In general, the compensation circuit may include 2 to 8 thin film transistors.

Furthermore, the driving circuits 910 and 920 formed on the non-display area NA of the substrate main body 111 may also include additional thin film transistors.

The organic light emitting element 70 includes an anode electrode that is a hole injecting electrode, a cathode electrode that is an electron injecting electrode and an organic emission layer disposed between the anode electrode and the cathode electrode.

Specifically, in the exemplary embodiment of the present invention, the display device includes a first thin film transistor 10 and a second thin film transistor 20 for one pixel area PE. The first thin film transistors 10 and the second thin film transistor 20 each include a gate electrode, a semiconductor, a source electrode and a drain electrode.

In FIG. 6, a capacitor line CL is illustrated in addition to a gate line GL, a data line DL and a common supply line VDD, but the exemplary embodiment of the present invention is not limited to the structure shown in FIG. 6. Therefore, the capacitor line CL may be omitted in some cases.

The data line DL is connected to a source electrode of the second thin film transistor 20, and the gate line GL is connected to a gate electrode of the second thin film transistor 20. Also a drain electrode of the second thin film transistor 20 is connected to the capacitor line CL through the capacitor 80. A node may be formed between the drain electrode of the second thin film transistor 20 and the capacitor 80 and connected to a gate electrode of the first thin film transistor 10. The drain electrode of the first thin film transistor 10 is connected to the common supply line VDD, and the source electrode is connected to an anode of the organic light emitting element 70.

The second thin film transistor 20 is used as a switching element selecting a pixel area PE from which light is emitted. When the second thin film transistor 20 is instantaneously turned on, charges are accumulated in the capacitor 80, and a charge amount that is accumulated at this time is in proportion to a potential of a voltage applied from the data line DL. Also when a signal in which a voltage increases in one frame period is input to the capacitor line CL while the second thin film transistor 20 is turned off, in a gate potential of the first thin film transistor 10, a level of the voltage applied based on the potential accumulated in the capacitor 80 increases depending on a voltage applied through the capacitor line CL. The first thin film transistor 10 is turned on when the gate potential is more than a threshold voltage. Then the voltage applied to the common supply line VDD is applied to the organic light emitting element 70 through the first thin film transistor 10, and the organic light emitting element 70 emits light.

A configuration of the pixel area PE described above is not limited to the above-described configuration, and can be variously modified within the range that can be easily modified by those of ordinary skill in the art.

Continuing from FIG. 5 and FIG. 6, a display device having the thin film transistor array panel 100 of FIG. 1 as a switching transistor will be described in detail with reference to FIG. 7 to FIG. 9.

A plurality of gate lines 121 including the first gate electrode 124a and a plurality of gate conductors including the third gate electrode 124c are positioned on the insulation substrate 110 made of transparent glass or plastic.

The gate lines 121 transfers a gate signal and extend mainly in a horizontal direction. Each of the gate lines 121 includes an end 129 having a large area used for connection to another layer or an external driving circuit, and the first gate electrode 124a extends upward from the gate line 121. When a gate driving circuit (not shown) generating a gate signal is integrated on the insulation substrate 110, the gate line 121 may extend to be directly connected to the gate driving circuit.

The third gate electrode 124c is isolated from the gate line 121, and includes a storage electrode 127 that extends downward, turns right instantaneously and extends upward.

The gate conductors 121 and 124c may be made of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), titanium (Ti), etc. However, these may include a multilayer structure including two conductive layers (not shown) having different physical properties. One of these conductive layers is made of a metal having low resistivity, for example, an aluminum-based metal, a silver-based metal or a copper-based metal to reduce a signal delay or voltage drop

On the other hand, the other of the conductive layers is made of another material, particularly, a material having excellent physical, chemical and electrical contact characteristics with indium tin oxide (ITO) and indium zinc oxide (IZO), i.e., a molybdenum-based metal, chromium, titanium or tantalum. Preferred examples of such a combination may include a chromium lower layer/an aluminum (alloy) upper layer and an aluminum (alloy) lower layer/a molybdenum (alloy) upper layer. However, the gate conductors 121 and 124c may be made of other various metals or conductors.

Lateral surfaces of the gate conductors 121 and 124c are inclined with respect to a surface of the insulation substrate 110 and may have an angle of inclination of about 30° to 80°.

The gate insulating layer 140 made of a silicon nitride (SiNx) or a silicon oxide (SiOx) is positioned on the gate conductors 121 and 124c.

The first oxide semiconductor 154a made of a titanium-indium-zinc oxide (TIZO) extends in parallel with the gate line 121 above the gate insulating layer 140 such that the first oxide semiconductor 154a and the gate electrode 124 overlap each other.

In the oxide semiconductor according to the exemplary embodiment of the present invention, the semiconductor layer made of a titanium-indium-zinc oxide (TIZO) semiconductor has been described by way of example, but the present invention is not necessarily limited thereto. When the oxide semiconductor is made of an oxide of a metal such as zinc (Zn), indium (In), gallium (Ga), tin (Sn), titanium (Ti) or a combination of a metal such as zinc (Zn), indium (In), gallium (Ga), tin (Sn) and titanium (Ti) with an oxide thereof. In addition, any oxide that exhibits a switching characteristic may be applied to the present invention.

The at least one etch stopper 160 may be positioned on the first oxide semiconductor 154a. The at least one etch stopper 160 is made of the first to third etch stoppers 160a, 160b and 160c, and the first etch stopper 160a may be positioned on the protruding upper portion of the first oxide semiconductor 154a. The second and third etch stoppers 160b and 160c are positioned to overlap a part of the both ends of the first oxide semiconductor 154a based on the first etch stopper 160a. The first to third etch stopper 160 protects the remaining portion of the first oxide semiconductor 154a such that the N+ region 157 may be formed in a part of the first oxide semiconductor 154a.

The second and third etch stoppers 160b and 160c are positioned in a region in which the first source electrode 173a and the first drain electrode 175a overlap the first oxide semiconductor 154a. The second and third etch stoppers 160b and 160c facilitate connection between the first gate electrode 124a and the second gate electrode 124b. A lateral surface of the first oxide semiconductor 154a is also inclined and has an angle of inclination of 30° to 80°.

A plurality of data conductors including a plurality of data lines 171, a plurality of driving voltage lines 172 and the first and second drain electrodes 175a and 175b are positioned on the first oxide semiconductor 154a and the at least one etch stopper 160.

The data line 171 transfers a data signal, and extends mainly in a vertical direction to intersect the gate line 121. Data lines 171 each includes an end 179 having a large area used for connection between the first source electrode 173a extending toward the first gate electrode 124a and another layer or an external driving circuit. When a data driving circuit (not shown) generating a data signal may be positioned on the insulation substrate 110, the data line 171 may extend to be directly connected to the data driving circuit.

The driving voltage lines 172 transfer a driving voltage and extend mainly in a vertical direction to intersect the gate line 121. Each of the driving voltage lines 172 includes a plurality of second source electrodes 173b extending toward the third gate electrode 124c. The driving voltage line 172 and the storage electrode 127 may overlap each other and be connected to each other.

The first and second drain electrodes 175a and 175b are isolated from each other. In addition, the first and second drain electrodes 175a and 175b are isolated from the data line 171 and the driving voltage line 172. The first source electrode 173a and the first drain electrode 175a face each other centering on the first gate electrode 124a and the first etch stopper 160a, and the second source electrode 173b and the second drain electrode 175b face each other centering on the third gate electrode 124c.

The second gate electrode 124b may be positioned on the first etch stopper 160a. The second gate electrode 124b and the first etch stopper 160a have similar plane shapes when viewed on a plane. In particular, the second gate electrode 124b has a narrower width than the first etch stopper 160a.

As shown in FIG. 8, the second gate electrode 124b has a similar planar shape to the first gate electrode 124a, but has a narrower width than the first gate electrode 124a.

The second gate electrode 124b may be formed simultaneously with the first source electrode 173a and the first drain electrode 175a and does not overlap the first source electrode 173a or the first drain electrode 175a. Further, the second gate electrode 124b has a smaller shape than the first etch stopper 160a and does not overlap the first gate electrode 124a either. Thus, in the second gate electrode 124b, a separate storage capacitor Cst is not formed.

The first gate electrode 124a and the second gate electrode 124b are connected through a contact hole 21 and may be applied with the same voltage. However, the present invention is not limited thereto, and the first gate electrode 124a and the second gate electrode 124b may be independently applied with a voltage.

The data conductors 171, 172, 175a and 175b may be made of a refractory metal such as molybdenum, chromium, tantalum and titanium or an alloy thereof and have a multilayer structure including a refractory metal film (not shown) and a low resistance conductive layer (not shown).

Examples of the multilayer structure may include a dual layer of a chromium or molybdenum (alloy) lower layer and an aluminum (alloy) upper layer and a triple layer of a molybdenum (alloy) lower layer, an aluminum (alloy) intermediate layer and a molybdenum (alloy) upper layer. However, the data conductors 171, 172, 175a and 175b and the second gate electrode 124b may be made of various metals or conductors in addition to this.

Similar to the gate conductors 121 and 124c, the lateral surfaces of the data conductors 171, 172, 175a and 175b and the second gate electrode 124b may also be inclined to have an angle of inclination of about 30° to 80° with respect to the surface of the substrate 110.

Ohmic contacts (not shown) are present only between the oxide semiconductors 154a and 154b thereunder and the data conductors 171, 172, 175a and 175b thereabove, and reduce contact resistance.

In the first oxide semiconductor 154a, there are portions that are not covered by the data conductors 171, 172, 175a and 175b but exposed between the first etch stopper 160a and the second etch stopper 160b and between the first etch stopper 160a and the third etch stopper 160c.

The N+ region 157 may be formed between the first etch stopper 160a and the second etch stopper 160b and between the first etch stopper 160a and the third etch stopper 160c.

The passivation layer 180 may be formed on the data conductors 171, 172, 175a and 175b and the exposed portion of the first oxide semiconductor 154a. The passivation layer 180 is made of an inorganic insulator, an organic insulator and a low dielectric constant insulator, which may include, for example, a silicon oxide (SiOx), a silicon nitride (SiNx), silicon oxynitride (SiON) or silicon oxyfluoride (SiOF). The surface of the passivation layer 180 may be flat. However, the passivation layer 180 may have a dual-layer structure of the lower inorganic layer and the upper organic layer such that excellent insulating characteristics of the organic layer are maintained and the exposed portion of oxide semiconductors 154a and 154b are not damaged.

In the passivation layer 180, a plurality of contact holes 182, 185a and 185b through which the end 179 of the data line 171 and the first and second drain electrodes 175a and 175b are exposed are formed. In addition, in the passivation layer 180 and the gate insulating layer 140, a plurality of contact holes 181 and 184 through which the end 129 of the gate line 121 and the third gate electrode 124c are exposed are formed.

A plurality of pixel electrodes 191, a plurality of connecting members 85 and a plurality of contact assistants 81 and 82 are formed on the passivation layer 180. The plurality of pixel electrodes 191, the plurality of connecting members 85 and the plurality of contact assistants 81 and 82 may be made of a transparent conductive material such as ITO or IZO or a reflective metal such as aluminum, silver or an alloy thereof.

The pixel electrode 191 is physically and electrically connected to the second drain electrode 175b through the contact hole 185b, and the connecting member 85 is connected to the third gate electrode 124c and the first drain electrode 175a through the contact holes 184 and 185a.

The contact assistants 81 and 82 are connected to the end 129 of the gate line 121 and the end 179 of the data line 171 through the contact holes 181 and 182. The contact assistants 81 and 82 supplement an adhesive property of the end 129 of the gate line 121 and the end 179 of the data line 171 with an external device and protect connection therebetween.

A partition 361 is formed on the passivation layer 180. The partition 361 surrounds an edge of the pixel electrode 191 like a bank to define an opening 365, and may be made of an organic insulator or an inorganic insulator. Further, the partition 361 may be made of a photoresist including a black pigment. In this case, the partition 361 serves as a light blocking member and a process of forming the partition 361 is simple.

An organic light emitting member 370 may be formed in the opening 365 above the pixel electrode 191 that is defined by the partition 361. The organic light emitting member 370 is made of an organic material that emits one unique light among primary colors such as the three primary colors red, green and blue. An organic light emitting display device displays a desired image using spatial superimposition of light of primary colors that the organic light emitting members 370 emit.

The organic light emitting member 370 may have a multi-layered structure including an auxiliary layer (not shown) for improving emission efficiency of an emission layer (not shown) that emits light in addition to the emission layer. The auxiliary layer includes an electron transport layer (not shown) and a hole transport layer (not shown) that are used to make balance between electrons and holes and an electron injecting layer (not shown) and a hole injecting layer (not shown) that are used to enhance injection of electrons and holes.

The common electrode 270 may be formed on the organic light emitting member 370. The common electrode 270 is applied with a common voltage Vss and made of a reflective metal such as calcium (Ca), barium (Ba), magnesium (Mg), aluminum (Al) and silver (Ag) or a transparent conductive material such as ITO or IZO.

In such an organic light emitting display device, the first gate electrode 124a and the second gate electrode 124b that are connected to the gate line 121 and the first source electrode 173a and the first drain electrode 175a that are connected to the data line 171 form a switching thin film transistor (TFT) Qs along with first oxide semiconductor 154a, and a channel of the switching TFT Qs is formed in the first oxide semiconductor 154a between the first source electrode 173a and the first drain electrode 175a. The third gate electrode 124c connected to the first drain electrode 175a, the second source electrode 173b connected to the driving voltage line 172 and the second drain electrode 175b connected to the pixel electrode 191 form a driving TFT Qd along with the second oxide semiconductor 154b, and a channel of the driving TFT Qd may be formed in the second oxide semiconductor 154b between the second source electrode 173b and the second drain electrode 175b. The pixel electrode 191, the organic light emitting member 370 and the common electrode 270 form an organic light emitting diode LD. In addition, the pixel electrode 191 serves as a cathode, and the common electrode 270 serves as an anode. The storage electrode 127 and the driving voltage line 172 which overlap each other form the storage capacitor Cst.

Such an organic light emitting display device emits light upward or downward with respect to the insulation substrate 110 to display an image. The opaque pixel electrode 191 and the transparent common electrode 270 are applied to an organic light emitting display device using a top emission method of displaying an image upward from the insulation substrate 110, and the transparent pixel electrode 191 and the opaque common electrode 270 are applied to an organic light emitting display device using a bottom emission method of displaying an image downward from the insulation substrate 110.

In the display device according to the exemplary embodiment of the present invention, since the first gate electrode 124a and second gate electrode 124b do not overlap the first source electrode 173a or the first drain electrode 175a, parasitic capacitance of the first gate electrode 124a and the second gate electrode 124b with the first source electrode 173a or the first drain electrode 175a may be prevented. Therefore, a signal delay occurring due to such parasitic capacitance may be prevented.

A display device according to another exemplary embodiment including the thin film transistor array panel according to the exemplary embodiment of the present invention will be described below.

Here, in the following description, structures that are the same as those of the display device according to the exemplary embodiment of the present invention will be denoted with the same reference numerals.

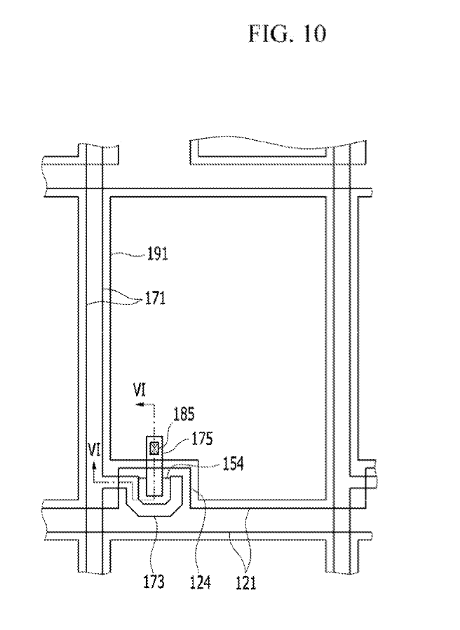

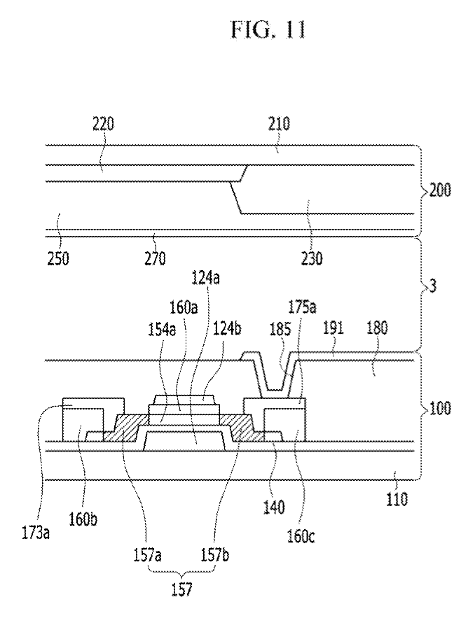

FIG. 10 is a top plan view schematically illustrating a structure of a display device according to another exemplary embodiment including the thin film transistor array panel of FIG. 1. FIG. 11 is a cross-sectional view taken along line VI-VI of FIG. 10.

Referring to FIG. 10 and FIG. 11, a liquid crystal display (LCD) including the thin film transistor array panel 100 according to the exemplary embodiment of the present invention includes the thin film transistor array panel 100, an upper panel 200 and a liquid crystal layer 3 interposed between the display panels 100 and 200, and a backlight unit 300 may be positioned under the thin film transistor array panel 100.

In addition, the arranged position of the backlight unit 300 is not limited to a position facing the thin film transistor array panel 100 and may be disposed in a position facing the upper panel 200.

Here, the thin film transistor array panel 100 of the liquid crystal display according to another exemplary embodiment of the present invention has the same details as that of FIG. 1 and thus the detailed description thereof will be omitted.

Next, referring to FIG. 11, the upper panel 200 will be described.

A light blocking member 220 may be positioned on an upper insulation substrate 210 made of transparent glass or plastic. The light blocking member 220 prevents light leakage in the pixel electrode 191 and defines an opening region facing the pixel electrode 191.

A plurality of color filter 230 are positioned on the upper insulation substrate 210 and the light blocking member 220. Color filters 230 are mostly present in a region surrounded by the light blocking member 220 and may extend long along a row of pixel electrodes 191.

Each of the color filters 230 may display one among primary colors such as three primary colors red, green and blue.

In the display device according to another exemplary embodiment of the present invention, a case in which the light blocking member 220 and the color filter 230 are positioned in the upper panel 200 has been described, but at least one of the light blocking member 220 and the color filter 230 may be positioned in the thin film transistor array panel 100.

An overcoat 250 may be positioned on the color filter 230 and the light blocking member 220. The overcoat 250 may be made of an (organic) insulator. In addition, the overcoat 250 prevents the color filter 230 from being exposed and is a flat plane. Such an overcoat 250 will be omitted.

Also a common electrode 270 may be positioned on the overcoat 250. The common electrode 270 is made of a transparent conductor such as ITO) and IZO and applied with a common voltage Vcom.

The liquid crystal layer 3 interposed between the thin film transistor array panel 100 and the upper panel 200 includes liquid crystal molecules having negative dielectric anisotropy, and the liquid crystal molecules may be aligned such that a longer axis thereof is vertical to the surfaces of the display panels 100 and 200 in a state in which there is no electric field.

The pixel electrode 191 and the common electrode 270 form the liquid crystal capacitor along with a liquid crystal layer 30 therebetween and maintain the applied voltage even after the thin film transistor is turned off.

The pixel electrode 191 may overlap a storage electrode line (not shown) to form a storage capacitor and thus enhance voltage retaining capability of a liquid crystal capacitor.

The backlight unit 300 of the display device according to another exemplary embodiment of the present invention illustrated in FIG. 11 may include a light source unit and a light guide. In addition, the backlight unit 300 supplies light.

The display device to which the thin film transistor array panel 100 according to the exemplary embodiment of the present invention is applied has been described above, but the present invention is not limited thereto. In addition, the description of the thin film transistor array panel 100 may be applied to any other display device.

Although the exemplary embodiments of the present invention have been described, it will be understood by those skilled in the art that various modifications and alternations may be made herein without departing from the scope and spirit of the invention as disclosed in the accompanying claims.

What is claimed is:

1. A thin film transistor array panel, comprising:
a substrate;
a first gate electrode positioned on the substrate;
a gate insulating layer positioned on the first gate;
an oxide semiconductor positioned on the gate insulating layer and including at least one channel region;
one or more etch stoppers positioned on the oxide semiconductor;
a second gate electrode, a source electrode and a drain electrode positioned on at least one of the etch stoppers;
a passivation layer formed on the second gate electrode, the source electrode and the drain electrode; and
a pixel electrode positioned on the passivation layer and connected to the drain electrode,
wherein the oxide semiconductor comprises an N+ region formed in a portion exposed through the at least one etch stopper.

2. The thin film transistor array panel of claim 1, wherein:
the N+ region has one side that is in contact with the gate insulating layer, and
the N+ region has the other side that is in contact with the source electrode or the drain electrode.

3. The thin film transistor array panel of claim 2, wherein:
the N+ region is positioned between the etch stoppers and includes first and second N+ regions positioned at both sides of the first gate electrode.

4. The thin film transistor array panel of claim 1, wherein:
the at least one etch stopper includes first to third etch stoppers.

5. The thin film transistor array panel of claim 4, wherein:
the first etch stopper is positioned on the first gate electrode, and
the second and third etch stoppers are formed at both sides of the first etch stopper and are partially in contact with the oxide semiconductor.

6. The thin film transistor array panel of claim 5, wherein:
the second and third etch stoppers are in contact with both ends of the oxide semiconductor and the gate insulating layer.

7. The thin film transistor array panel of claim 4, wherein:
the source electrode and the drain electrode cover the second etch stopper and the third etch stopper, respectively.

8. The thin film transistor array panel of claim 1, wherein:
the second gate electrode has a narrower width than the first gate electrode.

9. The thin film transistor array panel of claim 1, wherein:
the oxide semiconductor includes a titanium-indium-zinc oxide (TIZO) containing a combination of titanium (Ti), indium (In) and zinc (Zn).

10. The thin film transistor array panel of claim 1, wherein:
at least one channel region of the oxide semiconductor includes a first channel region and a second channel region, and
the first channel region is positioned above the gate insulating layer, and the second channel region is positioned under the first etch stopper.

11. The thin film transistor array panel of claim 1, wherein:
the passivation layer includes fluorine-containing silicon oxide (SiOF).

12. A method of manufacturing a thin film transistor array panel, the method comprising:
forming a first gate electrode on a substrate;
forming a gate insulating layer on the first gate electrode;
forming an oxide semiconductor including a channel region on the gate insulating layer;
forming one or more etch stoppers on the oxide semiconductor;
forming an N+ region in an exposed portion of the oxide semiconductor;
forming a second gate electrode, a source electrode, and a drain electrode on the at least one etch stopper; and
forming a passivation layer on the second gate electrode, the source electrode, and the drain electrode.

13. The method of claim 12, wherein:
the forming of the N+ region comprises
forming a photo resist (PR) on at least one of the etch stoppers and forming an N+ region using the PR as a mask,
wherein the N+ region is formed in a portion exposed through the at least one etch stopper in the oxide semiconductor.

14. The method of claim 12, wherein
the forming of the N+ region is performed by one of an ion implantation method and an inductively coupled plasma (ICP) method.

15. The method of claim 14, wherein
the inductively coupled plasma method comprises
injecting fluorine to form the N+ region.

16. The method of claim 12, wherein:
the N+ region has one side that is in contact with the gate insulating layer, and
the N+ region has the other side that is in contact with the source electrode or the drain electrode.

17. The method of claim 16, wherein:
the N+ region is positioned between the etch stoppers and includes first and second N+ regions positioned at both sides of the first gate electrode.

18. The method of claim 12, wherein
the forming of the source electrode and the drain electrode comprises
forming the source electrode and the drain electrode to be partially in contact with the oxide semiconductor.

19. The method of claim 12, wherein
the forming of the etch stoppers further comprises:
forming a first etch stopper on the oxide semiconductor; and
forming second and third etch stoppers at both sides of the first etch stopper.

20. The method of claim 19, wherein
the forming of the second and third etch stoppers comprises forming the second and third etch stoppers to be in contact with both ends of the oxide semiconductor and the gate insulating layer.
